(19) United States
(12) Patent Application Publication
(10) Pub. No.: US 2008/0315398 A1
(43) Pub. Date: Dec. 25, 2008

(54) PACKAGING SUBSTRATE WITH EMBEDDED CHIP AND BURIED HEATSINK

(76) Inventors: Hsing-Lun Lo, Taipei City (TW); Shih-Tsung Lin, Taoyuan County (TW); Hsien-Chieh Lin, Taoyuan County (TW); Kuo-Chun Chiang, Taoyuan (TW)

Correspondence Address: NORTH AMERICA INTELLECTUAL PROPERTY CORPORATION, P.O. BOX 506, MERRIFIELD, VA, 22116, US

(21) Appl. No.: 11/830,822

(22) Filed: Jul. 30, 2007

(30) Foreign Application Priority Data
Jun. 22, 2007 (TW) 096122630

(51) Int. Cl. H01L 23/48; H01L 23/10

(52) U.S. Cl. 257/693; 257/706; 257/E23.01; 257/E23.193

(57) ABSTRACT

An embedded chip package includes a substrate having a dielectric interposer, a first metal foil on a first surface and a second metal foil on a second surface of the substrate, wherein the substrate has a cavity recessed into the first surface; a metal heatsink embedded within the cavity; a semiconductor die mounted on a flat bottom of the metal heatsink; a dielectric layer covering the first surface of the substrate; at least one built-up circuit trace layer on the dielectric layer; a solder resist layer on the built-up circuit trace layer and on the dielectric layer; a heat-dissipating metal layer on the second metal foil; and heat-dissipating plugs connecting the flat bottom of the metal heatsink and the heat-dissipating metal layer.

### BACKGROUND OF THE INVENTION

1. Field of the Invention

The present invention relates to packaging substrates, and more particularly to an embedded chip package and packaging substrate thereof with improved heat dissipation performance.

2. Description of the Prior Art

With the rapid development of electronic technology, the number of I/O pads in microcontrollers is drastically increasing, and the power that each silicon chip consumes has also increased. In the future, microcontrollers may have more pins. For chip packages, electrical performance and dissipation control are two major challenges. In the aspect of electrical performance, chip packages have to maintain integrity of signals and operating frequency of semiconductor devices. In the aspect of dissipation control, chip packages also help dissipate heat generated by the silicon chip.

In addition to electrical performance and dissipation control, the small size of the microcontroller also demands smaller chip package size and denser I/O pad arrangements. In the future, a chip package may comprise several dies and opto-electronic elements, and minimizing the space between elements, maximizing the interconnectivity of elements, controlling signal frequency precisely, and matching impedance will be great issues for chip package designers. In conclusion, the prior art package technology, such as FCPGA, will not satisfy new requirements.

To solve the problems mentioned above, Intel Corp. has developed a Bumpless Build-Up Layer (BBUL) technology that embeds a die into a specialized, pc-board-like package, getting rid of solder bumps and connecting copper wires on the substrate directly.

According to the prior art BBUL technology, an adhesive tape is required. However, defects often occur during the process of routing wires on the surface layers. For example, after tearing off the tape, adhesive residue may be left on the bonding pads positioned on the active surface of the die. This problem decreases product quality, and increases the product cost so that the BBUL package may cost much more than the conventional package method.

Furthermore, because of the difference in the coefficients of thermal expansion of the die, the underfill and the substrate, cracks may occur during the routing process. Moreover, the heat dissipation performance also needs to be improved in the conventional BBUL package, so there are still a lot of problems to be solved in the conventional BBUL package.

### SUMMARY OF THE INVENTION

It is one object of the present invention to provide an improved embedded chip package and fabrication method thereof in order to solve the above-mentioned prior art problems.

It is another object of the present invention to provide an improved embedded chip package structure, wherein various components such as active or passive components may be embedded in the substrate to increase the usage of the substrate and to make the package lighter and thinner to meet the future trends.

According to the claimed invention, an embedded chip package comprises a substrate having a dielectric interposer, a first metal foil on a first surface of the substrate and a second metal foil on a second surface of the substrate, wherein the substrate has a cavity recessed into the first surface; a metal heatsink embedded within the cavity, wherein the metal heatsink includes a flat bottom; a semiconductor die mounted on the flat bottom of the metal heatsink; a dielectric layer covering the first surface of the substrate; at least one built-up circuit trace layer on the dielectric layer; a solder resist layer on the built-up circuit trace layer and on the dielectric layer; a heat-dissipating metal layer on the second metal foil; and a plurality of heat-dissipating plugs connecting the flat bottom of the metal heatsink and the heat-dissipating metal layer; wherein heat generated by the semiconductor die is dissipated by the metal heatsink, the heat-dissipating plugs and the heat-dissipating metal layer.

In one aspect, the first and second metal foils may be composed of copper, iron, gold or aluminum, preferably copper. The metal heatsink, the heat-dissipating plugs and heat-dissipating metal layer may be composed of copper, silver, iron, aluminum or alloys thereof, preferably copper.

The present invention is characterized in that the semiconductor die is integral with the packaging substrate and is situated within the metal heatsink of the packaging substrate to form an embedded chip package. The fabrication process is compatible with the conventional circuit built-up process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-14 are schematic, cross-sectional diagrams illustrating a method for fabricating an embedded chip package in accordance with the preferred embodiment of this invention.

### DETAILED DESCRIPTION

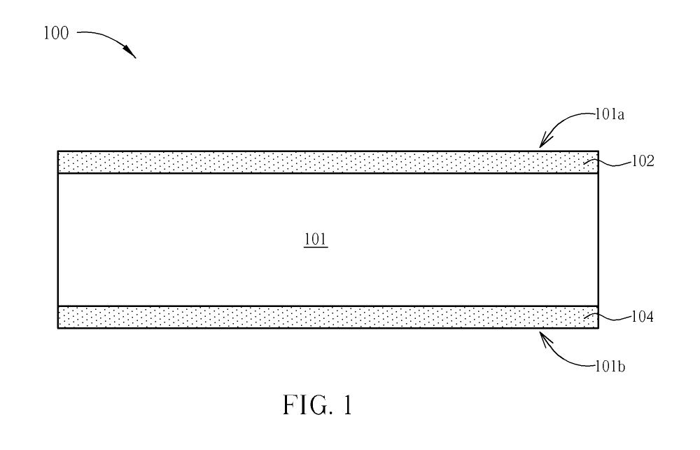

Please refer to FIGS. 1-14. FIGS. 1-14 are schematic, cross-sectional diagrams illustrating a method for fabricating an embedded chip package in accordance with the preferred embodiment of this invention.

As shown in FIG. 1, a substrate 100, such as double-sided copper clad laminate (CCL), is provided, which comprises a dielectric interposer 101, a first metal foil 102 positioned on a first surface 101a of the substrate 100, and a second metal foil 104 positioned on a second surface 101b of the substrate 100.

The dielectric interposer 101 may be made of glass fiber or resins. The first metal foil 102 and the second metal foil 104 may be composed of copper, iron, gold or aluminum, preferably copper. Generally, the thickness of the present invention embedded chip substrate is not critical. However, a preferable substrate thickness is less than 800 micrometers.

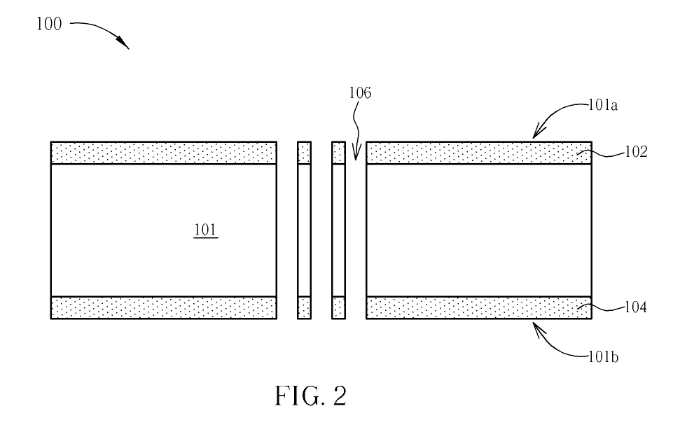

As shown in FIG. 2, a drilling process such as laser drilling or mechanical drilling is carried out to form a plurality of through holes 106 in the substrate 100. The through holes 106 traverse the first metal foil 102, the dielectric interposer 101 and the second metal foil 104.

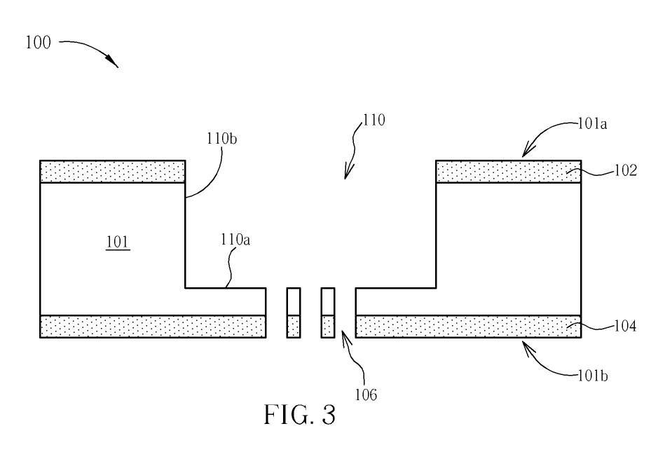

As shown in FIG. 3, another drilling process such as laser drilling or mechanical drilling is performed to rout the first surface 101a of the substrate 100, thereby forming a cavity 110 recessed into the dielectric interposer 101. The cavity 110 has a flat bottom 110a and sidewalls 110b, wherein the through holes 106 are located at the flat bottom 110a at this point.

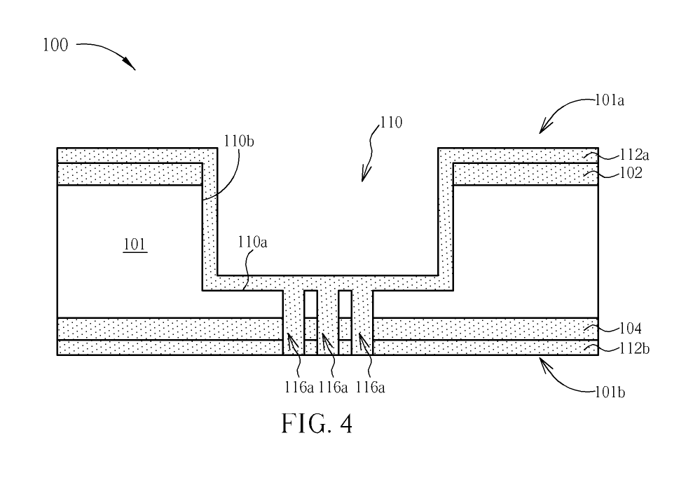

As shown in FIG. 4, a copper plating process is performed to plate the first surface 101a and second surface 101b of the substrate 100 with a copper layer 112a and copper layer 112b respectively. The through holes 106 at the flat bottom 110a of the cavity 110 are filled with the copper layers 112a and 112b, thereby forming heat-dissipating plugs 116a.

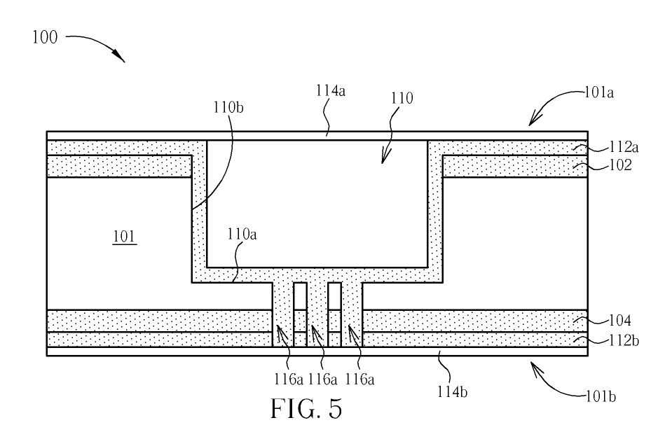

Subsequently, as shown in FIG. 5, a photoresist dry film 114a and a photoresist dry film 114b are formed on the first surface 101a and second surface 101b of the substrate 100.

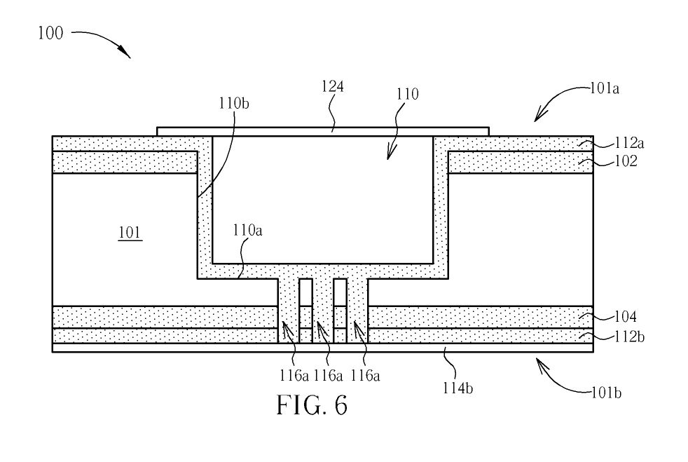

As shown in FIG. 6, the photoresist dry film 114a is then subjected to an exposure process and a development process to form a photoresist pattern 124 on the first surface 101a of the substrate 100. The photoresist pattern 124 on the first surface 101a covers the cavity 110 and also covers a portion of the copper layer 112a outside the cavity 110. At this point, the photoresist dry film 114b is intact and still covers the copper layer 112b on the second surface 101b of the substrate 100.

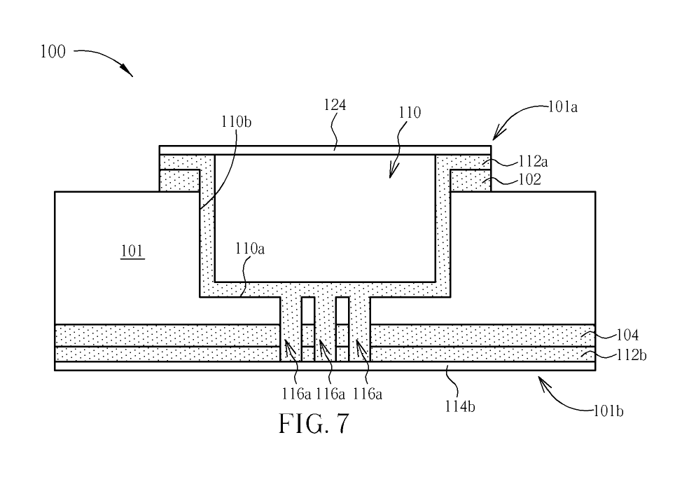

As shown in FIG. 7, using the photoresist pattern 124 on the first surface 101a of the substrate 100 and the photoresist dry film 114b on the second surface 101b of the substrate 100 as a hard mask, an etching process is carried out to remove the exposed copper layer 112a and the first metal foil 102 not covered by the photoresist pattern 124 from the first surface 101a of the substrate 100.

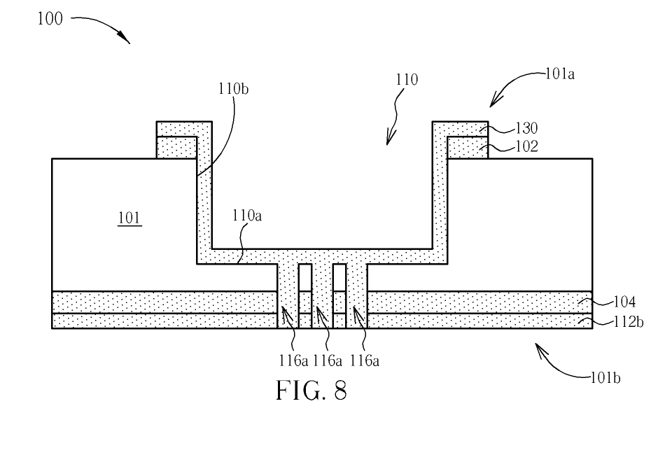

As shown in FIG. 8, after the etching process, the remanent photoresist pattern 124 on the first surface 101a of the substrate 100 and the photoresist dry film 114b on the second surface 101b of the substrate 100 are stripped off. At this point, the first surface 101a and second surface 101b of the substrate 100 are revealed.

After the photoresist pattern 124 and the photoresist dry film 114b are removed, a buried copper heatsink 130 is formed on the first surface 101a of the substrate 100. The bottom of the buried copper heatsink 130 is connected to the copper layer 112b and the second metal foil 104 on the second surface 101b of the substrate 100 through the heat-dissipating plugs 116a.

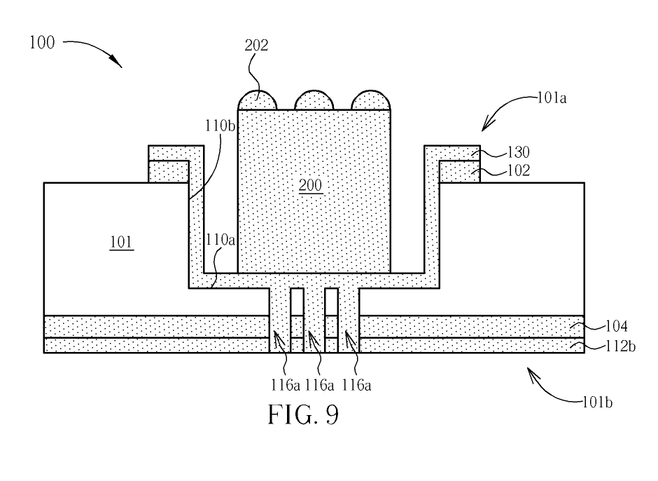

As shown in FIG. 9, a semiconductor chip or die 200 is mounted within the buried copper heatsink 130. The semiconductor die 200 is affixed to the bottom of the buried copper heatsink 130. The solder balls 202 on the bonding side of the semiconductor die 200 are outside the buried copper heatsink 130 to facilitate the electrical bonding between the die and a motherboard. To fix the semiconductor die 200, dot glue may be applied to the bottom or sidewall of the buried copper heatsink 130 first. The glue may be in liquid form and has good adhesion property and good heat-dissipating property. After applying the glue, the semiconductor die 200 is placed within the buried copper heatsink 130. The gap between the semiconductor die 200 and the buried copper heatsink 130 is then filled with an underfill (not shown).

Of course, the underfill between the semiconductor die 200 and the buried copper heatsink 130 may be omitted depending on the requirements of the product and process.

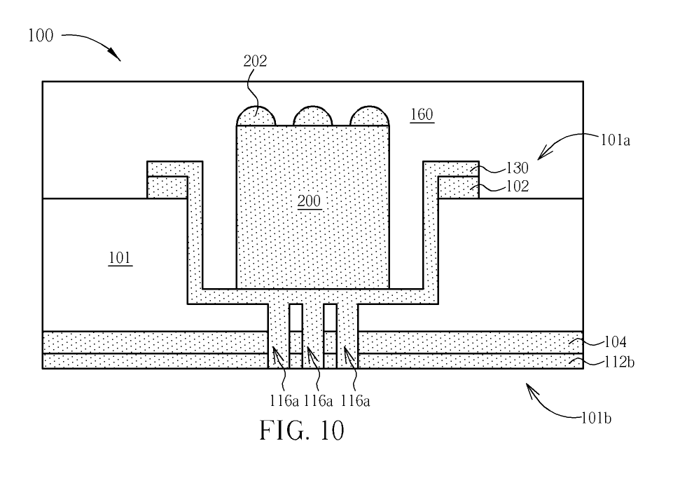

As shown in FIG. 10, a dielectric layer 160 is formed on the first surface 101a of the substrate 100. For example, the dielectric layer 160 may be composed of insulators such as epoxy resins or Ajinomoto Build-up Film (ABF). The dielectric layer 160 covers the semiconductor die 200 and the buried copper heatsink 130, and also fills the gap between the semiconductor die 200 and the buried copper heatsink 130.

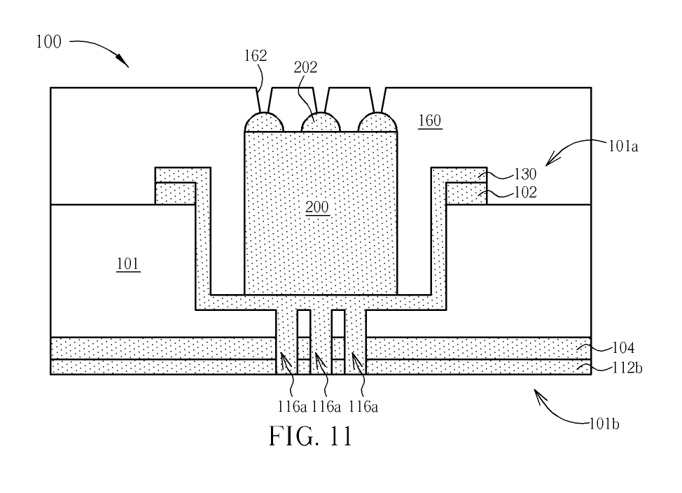

As shown in FIG. 11, a laser drilling process is performed to form a plurality of openings 162 in the dielectric layer 160. The openings 162 expose corresponding solder balls 202 on the bonding side of the semiconductor die 200.

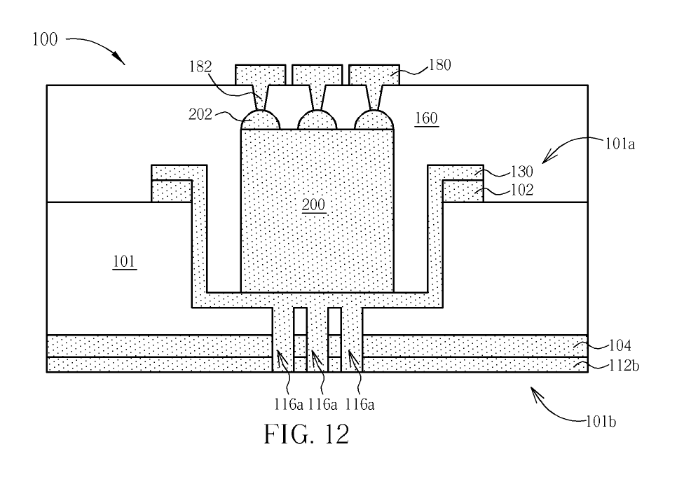

As shown in FIG. 12, a conventional built-up process including electroplating and etching steps are carried out to form conductive circuit traces 180 on the dielectric layer 160 and conductive plugs 182 between the conductive circuit traces 180 and the solder balls 202.

The aforesaid conventional built-up process may comprise electroplating copper layers, laminating photoresist dry films, exposing and developing, etching copper layers among others. Of course, the above-mentioned steps may be repeated to form multiple layers of conductive circuit traces on the substrate.

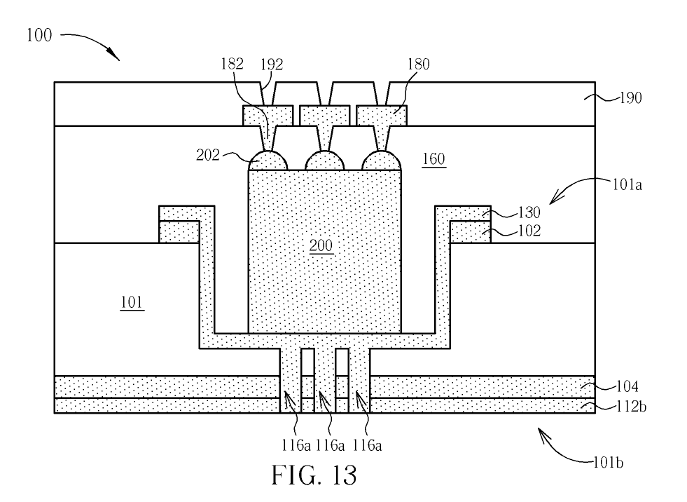

As shown in FIG. 13, after the built-up process, a solder resist layer 190 is formed on the first surface 101a of the substrate 100. Thereafter, an exposure and development process is performed to form a plurality of openings 192 in the solder resist layer 190. The openings 192 expose a portion of the conductive circuit traces 180. A solder resist layer may be optionally formed on the second surface 101b of the substrate 100. In another preferred embodiment, the solder resist layer on the second surface 101b may be omitted.

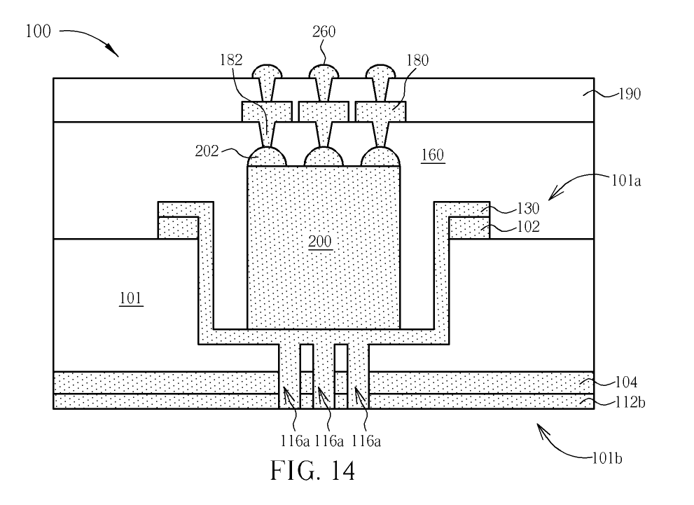

As shown in FIG. 14, subsequently, solder balls 260 are implanted on respective openings 192 for the electrical connection between the packaging substrate and the outer circuitry such as printed circuit board. The implantation of the solder balls 260 is known in the art.

The embedded chip package as depicted in FIG. 14 includes the embedded semiconductor die 200 having one side in direct contact with the monolithic, buried copper heatsink 130. The buried copper heatsink 130 has high heat-dissipating efficiency and is capable of dissipating heat generated from the semiconductor die 200 by way of the heat-dissipating plugs 116a underneath the semiconductor die 200 and the large-area copper layer 112b and the second metal foil 104 on the second surface 101b of the substrate 100.

Those skilled in the art will readily observe that numerous modifications and alterations of the device and method may be made while retaining the teachings of the invention.

What is claimed is:

1. An embedded chip package, comprising:
a substrate having a dielectric interposer, a first metal foil on a first surface of said substrate and a second metal foil on a second surface of said substrate, wherein said substrate has a cavity recessed into said first surface;
a metal heatsink embedded within said cavity, wherein said metal heatsink includes a flat bottom;
a semiconductor die mounted on said flat bottom of said metal heatsink;
a dielectric layer covering said first surface of said substrate;
at least one built-up circuit trace layer on said dielectric layer;
a solder resist layer on said built-up circuit trace layer and on said dielectric layer;
a heat-dissipating metal layer on said second metal foil; and
a plurality of heat-dissipating plugs connecting said flat bottom of said metal heatsink and said heat-dissipating metal layer;
wherein heat generated by said semiconductor die is dissipated by said metal heatsink, said heat-dissipating plugs and said heat-dissipating metal layer.

2. The embedded chip package according to claim 1 wherein the dielectric layer fills a gap between said semiconductor die and said metal heatsink.

3. The embedded chip package according to claim 1 further comprising a plurality of conductive plugs formed in said dielectric layer for electrically connecting said built-up circuit trace layer and said semiconductor die.

4. The embedded chip package according to claim 1 wherein said solder resist layer further comprises a plurality of apertures exposing a portion of said built-up circuit trace layer.

5. The embedded chip package according to claim 1 further comprises a plurality of solder balls for electrically connecting said substrate and an outer circuit board.

6. The embedded chip package according to claim 5 wherein said outer circuit comprise a printed circuit board.

7. The embedded chip package according to claim 1 wherein said first metal foil comprises copper, iron, gold and aluminum.

8. The embedded chip package according to claim 1 wherein said second metal foil comprises copper, iron, gold and aluminum.

9. The embedded chip package according to claim 1 wherein said heat-dissipating metal layer comprises copper.

10. The embedded chip package according to claim 1 wherein said dielectric interposer comprises glass fibers or resins.

11. The embedded chip package according to claim 1 wherein said dielectric layer comprises epoxy resins or Ajinomoto Build-up Film (ABF).

12. The embedded chip package according to claim 1 wherein said semiconductor die is affixed to said flat bottom of said metal heatsink using adhesive glue.

13. The embedded chip package according to claim 1 wherein said heat-dissipating plugs are copper plugs.

14. The embedded chip package according to claim 1 wherein said metal heatsink comprises copper.
